(19) United States
(12) Patent Application Publication
(10) Pub. No.: US 2025/0234585 A1
(43) Pub. Date: Jul. 17, 2025

(54) EXTENDED DRAIN METAL OXIDE SEMICONDUCTOR (EDMOS) FIELD EFFECT TRANSISTOR (FET) WITH DUAL THICKNESS SEMICONDUCTOR MATERIAL

(71) Applicant: GlobalFoundries U.S. Inc., Malta, NY (US)

(72) Inventors: Ming-cheng CHANG, Dresden (DE); Carsten Bernd GRASS, Dresden (DE); Peter JAVORKA, Dresden (DE)

(21) Appl. No.: 18/414,508

(22) Filed: Jan. 17, 2024

(51) Int. Cl. H01L 29/78; H01L 29/08; H01L 29/423; H01L 29/66

(52) U.S. Cl. CPC H10D 30/657; H10D 30/0281; H10D 62/159; H10D 64/021; H10D 64/516

(57) ABSTRACT

The present disclosure relates to semiconductor structures and, more particularly, to an extended drain metal oxide semiconductor (EDMOS) field effect transistor (FET) with a fully depleted region comprising a dual thicknesses semiconductor material and methods of manufacture. The structure includes: a semiconductor on insulator (SOI) material including a first portion with a first thickness and a second portion with a second thickness; a gate structure on the SOI material over the first portion with the first thickness; and sidewall spacers adjacent to the gate structure, with at least one sidewall spacer extending over both the first portion with the first thickness and the second portion with the second thickness.

### BACKGROUND

The present disclosure relates to semiconductor structures and, more particularly, to an extended drain metal oxide semiconductor (EDMOS) field effect transistor (FET) with a fully depleted region comprising a dual thicknesses semiconductor material and methods of manufacture.

In EDMOS with FDSOI structures, an SOI layer is placed on top of an ultra-thin buried oxide (BOX) layer which is placed on top of a silicon substrate. The SOI layer is very thin and creates a transistor channel between the source and drain. In other words, the SOI layer creates the FDSOI depletion regime for breakdown voltage (BVDSS) Due to the SOI layer being so thin, there is no need for channel doping.

### SUMMARY

In an aspect of the disclosure, a structure that includes: a semiconductor on insulator (SOI) material including a first portion with a first thickness and a second portion with a second thickness; a gate structure on the SOI material over the first portion with the first thickness; and sidewall spacers adjacent to the gate structure, with at least one sidewall spacer extending over both the first portion with the first thickness and the second portion with the second thickness.

In an aspect of the disclosure, a structure comprises: a semiconductor on insulator (SOI) layer comprising a first thickness and a second thickness, the first thickness being less than the second thickness; a gate structure on the SOI layer over the first thickness; a source region on a first side of the gate structure over the first thickness; a drain region on a second side of the gate structure over the second thickness; and at least one sidewall spacer on sidewalls of the gate structure and extending to the drain region.

In an aspect of the disclosure, a method comprises: forming a semiconductor on insulator (SOI) material including a first portion with a first thickness and a second portion with a second thickness; forming a gate structure on the SOI material over the first portion with the first thickness; and forming sidewall spacers adjacent to the gate structure, with at least one sidewall spacer extending over both the first portion with the first thickness and the second portion with the second thickness.

### BRIEF DESCRIPTION OF THE DRAWINGS

The present disclosure is described in the detailed description which follows, in reference to the noted plurality of drawings by way of non-limiting examples of exemplary embodiments of the present disclosure.

FIGS. 1-6 show cross-sectional views of fabrication processes and a final structure (FIG. 6) of a dual thicknesses device in accordance with aspects of the present disclosure.

### DETAILED DESCRIPTION

The present disclosure relates to semiconductor structures and, more particularly, to an extended drain metal oxide semiconductor (EDMOS) field effect transistor (FET) with a fully depleted semiconductor on insulator (FDSOI) region comprising a dual thicknesses semiconductor material and methods of manufacture. In embodiments, the EDMOS utilizes a semiconductor on insulator material that has a dual thicknesses. Advantageously, the structures described herein exhibit increased structural flexibility while retaining low on-state gate resistance (Ron), i.e., lower power consumption and higher performance and reliability.

The structures of the present disclosure can be manufactured in a number of ways using a number of different tools. In general, though, the methodologies and tools are used to form structures with dimensions in the micrometer and nanometer scale. The methodologies, i.e., technologies, employed to manufacture the structures of the present disclosure have been adopted from integrated circuit (IC) technology. For example, the structures are built on wafers and are realized in films of material patterned by photolithographic processes on the top of a wafer. In particular, the fabrication of the structures uses three basic building blocks: (i) deposition of thin films of material on a substrate, (ii) applying a patterned mask on top of the films by photolithographic imaging, and (iii) etching the films selectively to the mask. In addition, precleaning processes may be used to clean etched surfaces of any contaminants, as is known in the art. Moreover, when necessary, rapid thermal anneal processes may be used to drive-in dopants or material layers as is known in the art.

FIGS. 1-6 show cross-sectional views of fabrication processes and a final structure (FIG. 6) of a dual thicknesses device in accordance with aspects of the present disclosure. In embodiments, the final structure shown in FIG. 6 may be an EDMOS with a FDSOI layer, e.g., thin SOI layer.

In FIG. 1, a semiconductor substrate comprises a semiconductor on insulator (SOI) layer 14 bonded to a top of a buried insulator layer 12. The buried insulator layer 12 is bonded to a top of a substrate layer (e.g., handle substrate) 10. In an example embodiment, the SOI layer 14 may initially be about 12 nm thick.

In embodiments, the substrate layer 10 and SOI layer 14 can include a suitable semiconductor material. In embodiments, the suitable semiconductor material includes, but is not limited to, Si, SiGe, SiGeC, SiC, GaAs, InAs, InP, and other III/V or II/VI compound semiconductors. The SOI layer 14 may also comprise any suitable single crystallographic orientation (e.g., a (100), (110), (111), or (001) crystallographic orientation). In embodiments, the semiconductor substrate 10 may be a bulk semiconductor substrate. The buried insulator layer 12 may be an insulating material comprising any suitable material, including silicon oxide, sapphire, other suitable insulating materials, and/or combinations thereof. An exemplary insulator layer may be a buried oxide layer (BOX). In embodiments, the buried insulator layer 12 can have a thickness of about 25 nm or less (preferably 20 nm or less).

FIG. 1 further shows an oxide and/or nitride layer 16 deposited on the SOI layer 14. The oxide/nitride layer 16 can be deposited by any conventional deposition process such as a chemical vapor deposition (CVD) process, amongst others known in the art.

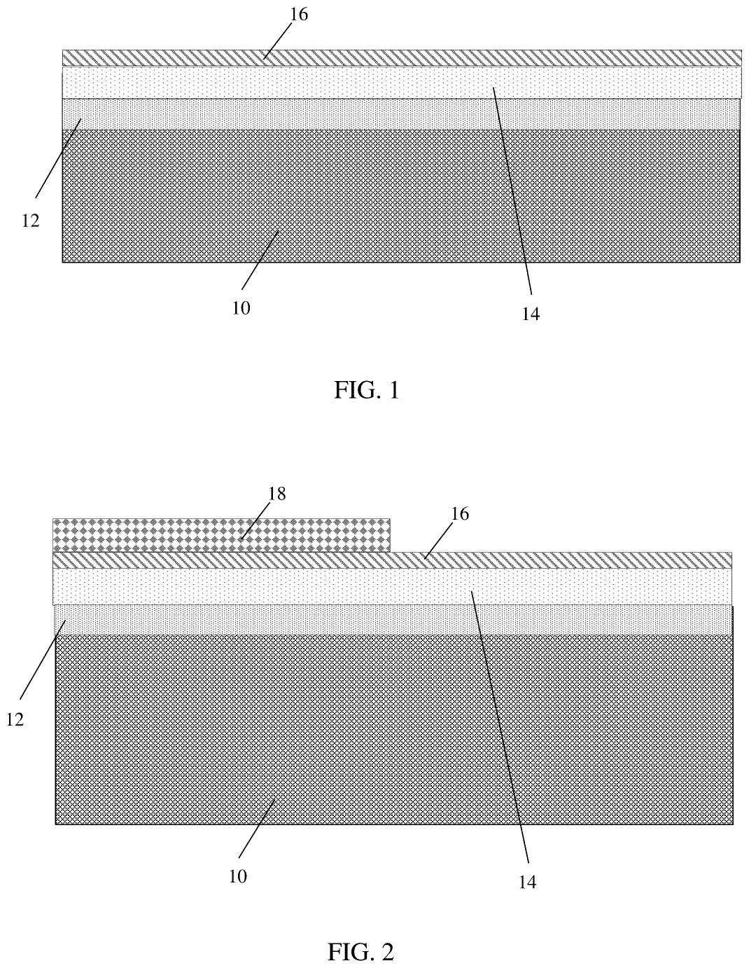

In FIG. 2, a photoresist mask 18 may be deposited and patterned over a portion of the oxide/nitride layer 16. In embodiments, the photoresist mask 18 is blanket deposited over the structure, followed by a patterning process using conventional lithography and etching process(es). The unprotected or exposed oxide/nitride layer 16 may be subjected to an etching process to expose the underlying SOI layer 14.

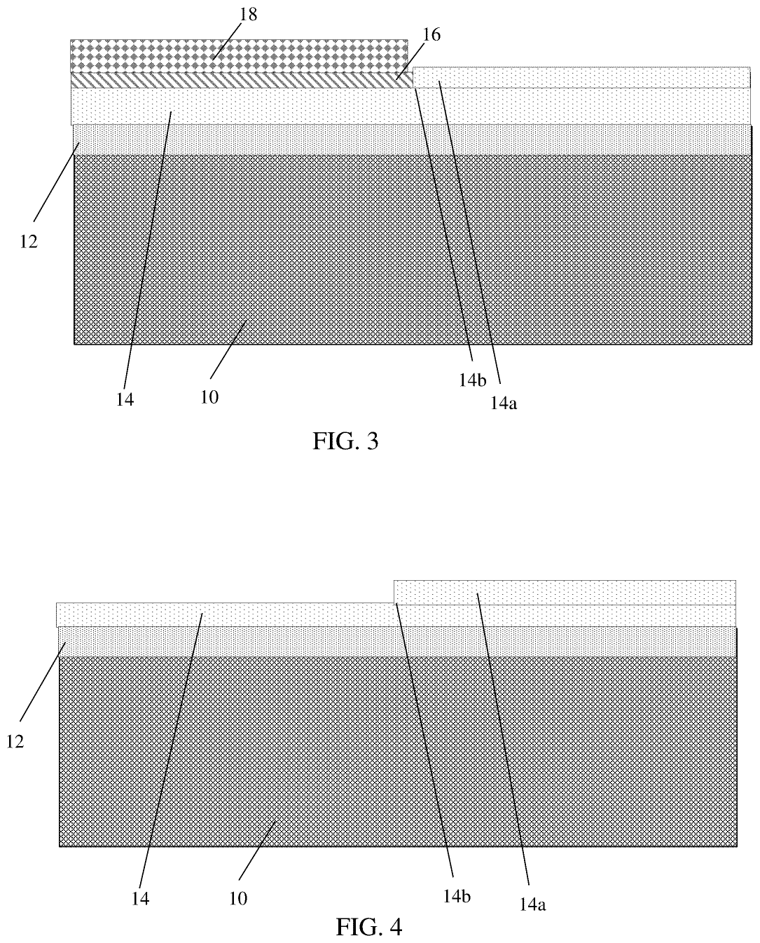

As shown in FIG. 3, an etching process with a selective chemistry, e.g., reactive ion etching (RIE), will be used to remove the exposed oxide/nitride layer 16 and to expose the underlying semiconductor layer 14. A semiconductor material 14a may be deposited on the exposed SOI layer 14. In more specific embodiments, semiconductor material 14a is epitaxially grown on the SOI layer 14, effectively increasing the thickness of the SOI material of the SOI layer 14. In exemplary embodiments, the semiconductor material 14a may be the same material as the underlying SOI layer 14, grown over the SOI layer 14 to form an extended drain side of the device, e.g., drift region. The semiconductor material 14a may undergo a thinning process using, for example, conventional oxidation process(es), to reach a total thickness of the SOI layer 14 and the semiconductor material 14a to about 8 nm to 25 nm thick, and preferably about 20 nm.

In embodiments, a transition point of the SOI layer 14 from the thinner portion of the SOI layer 14 to the thicker portion of the SOI layer 14a is shown by transition point 14b. The thicker portion of the semiconductor material 14a results in a lower resistance to reduce drain source on resistance (RDSon) while maintaining BVDSS. It should be understood by those of skill in the art that the transition point 14b may be moved via the patterning of the photoresist mask 18 to address different design and performance parameters.

As shown in FIG. 4, the photoresist mask 18 may be stripped using oxygen ashing processes or other stripants. The oxide/nitride layer 16 may also be removed using conventional etching processes or chemical mechanical polishing (CMP). The original SOI layer 14 may undergo a thinning process using, for example, conventional oxidation process(es). In exemplary embodiments, the SOI layer 14 may be thinned to approximately 6 nm; although other thicknesses are contemplated herein. Due to its small thickness, the SOI layer 14 can include a low doping, which makes the SOI layer 14 fully depleted (i.e., substantially devoid of either electron or hole carriers) when unbiased. Also, the thickness of the SOI layer 14 can allow for more stable control of electron flow within the SOI layer 14 (i.e., reduced leakage currents).

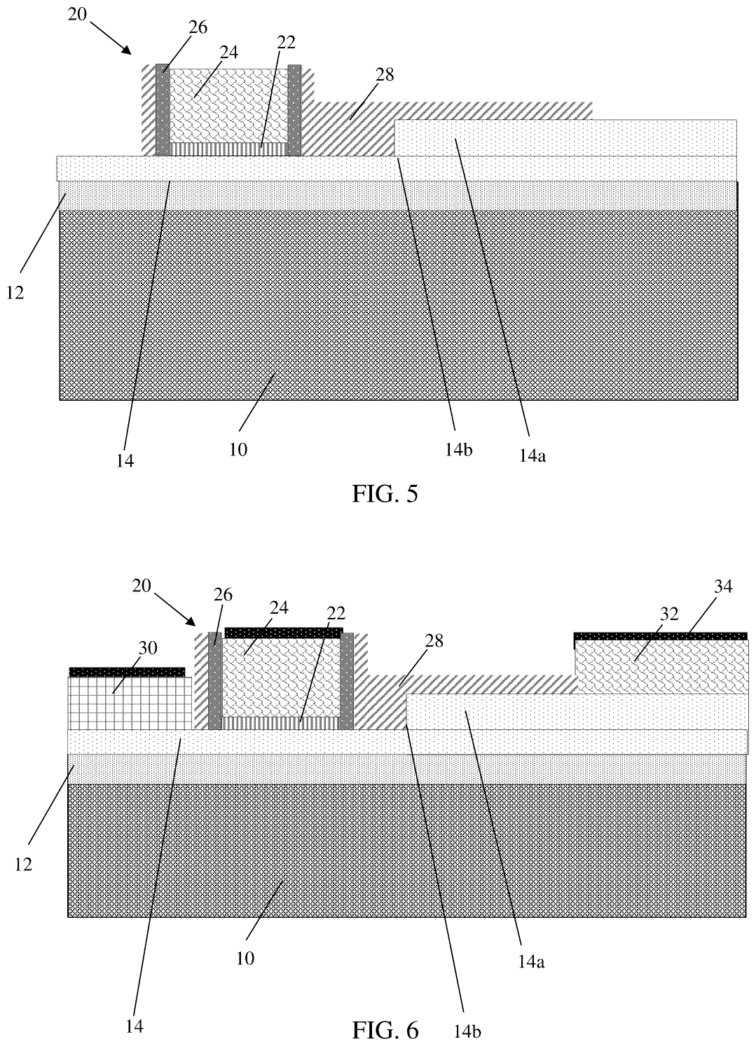

As shown in FIG. 5, a gate structure 20 may be formed on the thinner portion of the SOI layer 14 using conventional gate formation processes, e.g., deposition and patterning processes. For example, following the removal of the oxide/nitride layer 16, shown in FIG. 4, a gate dielectric material 22 may be deposited on the SOI layer 14, followed by a gate electrode 24, and sidewall spacers 26 and 28.

In embodiments, the gate dielectric material 22 can also be deposited by a blanket deposition process, e.g., atomic layer deposition (ALD) or plasma enhanced chemical vapor deposition (PECVD). The gate dielectric material 22 can be any high-k or low-k dielectric material depending on the specific application and required performance parameters. For example, the high-k dielectric material can be, but not limited to, e.g., a SiO2 or a high-k gate dielectric material, e.g., HfO₂ Al₂O₃, Ta₂O₃, TiO₂, La₂O₃, SrTiO₃, LaAlO₃, ZrO₂, Y₂O₃, Gd₂O₃, and combinations including multilayers thereof; whereas the low-k dielectric can be SiN material.

In embodiments, the gate electrode 24 may be polysilicon material deposited by CVD processes and highly doped with either a p-type or n-type dopant during to elevate its electrical conductivity. Following the deposition process, the gate electrode material and the gate dielectric material are patterned using conventional lithography and etching processes as is known in the art.

The sidewall spacers 26, 28 are provided on side surfaces or sidewalls of the patterned gate electrode 24 and gate dielectric material 22. In embodiments, the sidewall spacers 26, 28 may be formed by depositing a conformal layer of a dielectric material, e.g., SiO₂, and etching the material using, e.g., reactive ion etching. In embodiments, the sidewall spacer 26 is an inner sidewall spacer arranged between the sidewall spacer 28 (i.e., the outer sidewall spacer) and the gate electrode 24 and gate dielectric material 22. In embodiments, the sidewall spacer 26 is thinner than the sidewall spacer 28. Also, as shown in FIG. 5, the sidewall spacer 28 extends beyond the thinner portion of the SOI layer 14 to the thicker portion of the SOI layer 14 comprising the semiconductor material 14a, e.g., over a drift region on a drain side of the device. More specifically, the sidewall spacer 28 extends to the drain region 32 (as shown in FIG. 6) and overlays both a section of the thin portion of the SOI layer 14 and a section of the thick portion of the SOI layer (over the semiconductor material 14a).

As shown in FIG. 6, a source region 30 and a drain region 32 may be formed adjacent to the gate structure 20 using conventional epitaxial growth processes with in-situ doping as is known in the art. In embodiments, the source region 30 and drain region 32 can be raised source and drain regions. In embodiments, the source region 30 and drain region 32 include n-type doped semiconductor materials such as, for example, Arsenic (As), Phosphorus (P) and Antimony (Sb), among other suitable examples.

Still referring to FIG. 6, the source region 30, drain region 32 and gate structure 20 may be subjected to a silicide process to form silicide contacts 34. As should be understood by those of skill in the art, the silicide process begins with deposition of a thin transition metal layer, e.g., nickel, cobalt or titanium, over fully formed and patterned semiconductor devices (e.g., doped or ion implanted source region 30, drain region 32 and respective gate structure 20). After deposition of the material, the structure is heated allowing the transition metal to react with exposed silicon (or other semiconductor material as described herein) in the active regions of the semiconductor device (e.g., source region 30, drain region 32, and gate structure 20) forming a low-resistance transition metal silicide. Following the reaction, any remaining transition metal is removed by chemical etching, leaving silicide in the active regions of the structure. It should be understood by those of skill in the art that silicide contacts will not be required on the structure when a gate structure 20 is composed of a metal material.

The structures can be utilized in system on chip (SoC) technology. The SoC is an integrated circuit (also known as a “chip”) that integrates all components of an electronic system on a single chip or substrate. As the components are integrated on a single substrate, SoCs consume much less power and take up much less area than multichip designs with equivalent functionality. Because of this, SoCs are becoming the dominant force in the mobile computing (such as in Smartphones) and edge computing markets. SoC is also used in embedded systems and the Internet of Things.

The method(s) as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

1. A structure comprising:
a semiconductor on insulator (SOI) material including a first portion with a first thickness and a second portion with a second thickness;
a gate structure on the SOI material over the first portion with the first thickness; and
sidewall spacers adjacent to the gate structure, with at least one sidewall spacer extending over both the first portion with the first thickness and the second portion with the second thickness.

2. The structure of claim 1, wherein the sidewall spacers comprise two sidewall spacers with different thicknesses.

3. The structure of claim 2, wherein the at least one sidewall spacer extends to a drain side of the gate structure.

4. The structure of claim 3, wherein the at least one sidewall spacer is an outer sidewall spacer that is thicker than an inner sidewall spacer.

5. The structure of claim 1, wherein the first thickness is thinner than the second thickness.

6. The structure of claim 5, wherein the SOI material comprising the first portion with the first thickness comprises fully depleted SOI material.

7. The structure of claim 6, wherein the second portion comprises a drain side of the gate structure.

8. The structure of claim 1, wherein the second thickness comprises about 8 nm to about 25 nm.

9. The structure of claim 8, wherein the second thickness comprises about 20 nm.

10. The structure of claim 6, wherein the second portion comprises a drift region on the drain side.

11. The structure of claim 1, wherein the first thickness comprises about 6 nm.

12. A structure comprising:
a semiconductor on insulator (SOI) layer comprising a first thickness and a second thickness, the first thickness being less than the second thickness;
a gate structure on the SOI layer over the first thickness; and
a source region on a first side of the gate structure over the first thickness;
a drain region on a second side of the gate structure over the second thickness; and
at least one sidewall spacer on sidewalls of the gate structure and extending to the drain region.

13. The structure of claim 12, wherein the at least one sidewall spacer comprises two sidewall spacers.

14. The structure of claim 13, wherein the two sidewall spacers comprise different dimensions.

15. The structure of claim 13, wherein the at least one sidewall spacer extends over both the first thickness and the second thickness of the SOI layer.

16. The structure of claim 15, wherein a second of the two sidewall spacers comprises an inner sidewall spacer over the first thickness and the at least one sidewall is an outer sidewall extending over a drift region.

17. The structure of claim 12, wherein the first thickness comprises fully depleted semiconductor on insulator material.

18. The structure of claim 12, wherein the second thickness comprises two layers of SOI layer.

19. The structure of claim 12, wherein the first thickness comprises about 6 nm.

20. A method comprising:
forming a gate structure between a raised source and raised drain;
forming a silicon on insulator (SOI) layer including a first portion with a first thickness under the gate;
forming a second portion of the SOI layer with a second thickness adjacent to the gate structure and the raised drain; and
forming two sidewall spacers adjacent to the gate structure.
